(19) United States
(12) Patent Application Publication
(10) Pub. No.: US 2017/0257974 A1
(43) Pub. Date: Sep. 7, 2017

(54) PHASE CHANGE MATERIAL-CARBON NANOTUBE-METAL SUBSTRATE COMPOSITES FOR THERMAL STORAGE AND CONTROL OF HEAT GENERATING DEVICES

(71) Applicant: Carbice Corporation, Atlanta, GA (US)

(72) Inventors: Baratunde Cola, Atlanta, GA (US); Craig Green, Atlanta, GA (US)

(21) Appl. No.: 15/452,205

(22) Filed: Mar. 7, 2017

Related U.S. Application Data
(60) Provisional application No. 62/304,765, filed on Mar. 7, 2016.

(51) Int. Cl. H05K 7/20; F28F 21/02; B82Y 30/00

(52) U.S. Cl. CPC H05K 7/20; B82Y 30/00; F28F 21/02; H05K 7/20336; H05K 7/20509; H05K 7/2039; Y10S 977/742; F28F 2255/20; F28F 2225/04

(57) ABSTRACT

Phase change material-carbon nanotube-metal substrate composites and methods of making and using thereof are described herein. Such composites allow for thermal storage and passive or combined active/passive thermal control of heat generating sources, such as in electronic devices.

### CROSS-REFERENCE TO RELATED APPLICATIONS

This application claims benefit of U.S. Provisional Application No. 62/304,765, filed Mar. 7, 2016, which, where permissible, is specifically incorporated reference herein in its entirety.

### FIELD OF THE INVENTION

This invention is in the field of phase change material-carbon nanotube-metal substrate composites, particularly for thermal control in heat generating devices and methods of making and using thereof.

### BACKGROUND OF THE INVENTION

As the semiconductor industry continually strives to increase the power density of single chip packages, thermal management remains a critical challenge toward realizing both performance and reliability metrics.

Passive thermal control via temporary energy storage utilizing the large latent heat capacity of materials that change phase near the operating temperatures of heat generating devices has been explored with great interest in the past. A key limitation of these systems is that the volume of phase change material available for energy storage during operation of the heat generating device is limited by the thermal conductivity of the phase change material. From Fourier's law of heat conduction, the distance that a melt front can travel from a heat source before the device overheats is proportional to the thermal conductivity of the thermal storage medium and the heat flux generated by the device.

As such, additives to the phase change material that increase thermal conductivity are an attractive means of improving the functionality of phase change materials for thermal control. Carbon nanotubes, with their excellent thermal conductivity make an appealing choice as additives for enhancement of phase change materials. Effectively implementing carbon nanotube phase change material composites, however, requires addressing several hurdles including: (1) significant effort required to disperse carbon nanotubes within phase change materials; (2) a random dispersion of carbon nanotubes results in large numbers of interfacial boundaries that interfere with effective heat transfer; and (3) dispersions of carbon nanotubes tend to slowly be pumped out of the phase change material-carbon nanotube matrix (PCM-CNT) due to the expansion and contraction of the phase change material during melting and solidification cycles.

Thus, there exists a need for phase change material-carbon nanotube composites that include vertically aligned carbon nanotubes attached to a metal substrate, as well as methods of making thereof.

Therefore, it is an object of the invention to provide for phase change material-carbon nanotube-metal substrate composites that include vertically aligned carbon nanotubes grown on and well attached to a metal substrate, as well as methods of making/assembling and using thereof.

It is also an object of the invention to provide methods for using phase change material-carbon nanotube-metal substrate for thermal control of heat generating devices.

### SUMMARY OF THE INVENTION

Phase change material-carbon nanotube-substrate (PCM-CNT-substrate) composites and methods of making and using thereof are described herein.

Arrays and sheets of vertically aligned carbon nanotubes on substrates or supports are coated with, dispersed within, infiltrated by, or filled with a phase change material(s) (PCMs). The PCM material acts as a thermal storage medium capable of storing heat energy. The PCM can be applied as described below. In some embodiments, the PCM is, or contains, one or more oligomeric materials, polymeric materials, or combinations thereof. In other embodiments, the PCM is, or contains, one or more non-polymeric materials. In some embodiments, the PCM is or contains a mixture of oligomeric and/or polymeric material and non-polymeric materials. In yet other embodiments, the PCM is, or contains, a low melting temperature metal. In still other embodiments, the PCM is or contains metallic nanoparticles.

A variety of PCM materials can be used to coat the CNT arrays or sheets or fill the space(s) between the nanotubes of the arrays or sheets. In preferred embodiments, the PCM can fill all or substantially all of the free volume or void space(s) between nanotubes. As used herein, “substantially all” refers to at least about 99.9%, 99%, 98%, 97%, 96%, or 95% filling of spaces, cavities, or void spaces present in the CNT array or sheet.

In particular embodiments, the PCM can cause a decrease in the thermal resistance of the CNT array or sheet. PCM materials can be applied in liquid or powder spray form to conformally coat the tips or sidewalls of the CNTs or to fill in the free volume (i.e., between tubes) present in a CNT array or sheet. It is also desirable that the PCM material be reflowable as the interface is assembled using, for example, solvent, heat or some other easy to apply source. The PCM must be thermally stable up to at least about 120° C., 130° C., 140° C., 150° C., 160° C., 170° C., 180° C., 190° C., or 200° C. Preferably, the PCM should be thermally stable down to 0° C., −24° C. or −55° C. In some embodiments, the coating can be readily removable, such as by heat or dissolution in a solvent, to allow for “reworking” of the PCM. “Reworking”, as used herein, refers to breaking the PCM (i.e., removing the coating) by applying solvent or heat in order to clean or remove the PCM for application of a new PCM.

The CNT arrays or sheets can be coated with, dispersed within, or infiltrated by, and/or filled in with a low melting temperature metal or metal alloys or combinations thereof. The one or more metals may be applied to the CNT arrays or sheets using any known technique. The one or more metals can be adsorbed to the distal ends and/or sidewalls of the CNTs to bond the distal ends and/or sidewalls of the CNTs to a surface, reduce thermal resistance between the CNT array or sheet and a surface, or combinations thereof. Exemplary low melting temperature metals include, but are not limited to, bismuth, indium, tin, gallium, and combinations thereof.

The carbon nanotube arrays or sheets can be prepared on a support or substrate using techniques known in the art. Flowable or phase change materials, as described herein, may be applied to or infiltrated into the CNT array or sheet to displace the air or any void space present between CNTs and improve contact between the distal ends and/or sidewalls of CNTs and a surface, and as a result reduce thermal resistance of the array or sheet and the contact between the array or sheet and a surface, or combinations thereof. In related embodiments, the PCM can further provide structural integrity to the vertically aligned CNT array or sheet. Flowable or phase change materials can be applied to CNT arrays using a variety of methods known in the art.

In one embodiment, the phase change material wets the CNTs and infiltrates the CNT array via capillary action or wicking action. In an embodiment, the PCM is dissolved in a suitable solvent that allows it to easily infiltrate the array, followed by evaporation of the solvent. In another embodiment, the PCM is infiltrated into the array in the form of solid particulate form which may be polymeric, non-polymeric, metallic, or ceramic nanoparticles that are reflowed and agglomerated following infiltration. Preferably, the size of the solid particulates is chosen such that the average diameter is smaller than the nanotube-to-nanotube spacing distance with the array. In one embodiment, the PCM is infiltrated into the array via an in situ chemical reaction, such as electrodeposition.

In another embodiment, the phase change material is infiltrated into the array or sheet via application of a pressure gradient. In preferred embodiments, the pressure gradient that the array or sheet can sustain without collapse or delamination from the substrate is enhanced to due superior adhesion between the CNTs and the metal substrate. This superior adhesion may be quantified through the array's ability to endure mechanical agitation such as sonication, as discussed above. In such an embodiment, the CNT array can survive/withstand sonication in an ultrasonic bath in the presence of a solvent, signifying sufficient adhesion to survive pressure based infiltration methods for applying one or more PCMs thereto.

In yet another embodiment, the pressure gradient required for infiltration can be reduced by modifying the surface energy of the CNTs of the array or sheet through an applied coating, such as through application of polymeric, non-polymeric, or metallic nanoparticles, as described above. In one embodiment, the surface energy of the CNT array is modified through the introduction of one or more structural defects or non-carbon species into the nanotubes.

Examples of suitable flowable or phase change materials include, but is not limited to, fatty acids, natural waxes, paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some embodiments, the coating material, such as a non-polymeric coating material and the flowable or phase change material are the same material or materials.

The CNT arrays or sheets which are coated, dispersed by, or filled in with a PCM can be abutted or bonded to a thermally conducting substrate to prepare a device for evaluating thermal resistance or a heat source, such as an integrated circuit package, to form a commercial product. In some embodiments, the PCM can further impart adhesive properties to the composite on the metal substrate. The CNT array of the composite may also provide stress relief to the phase change material by providing structural reinforcement and load bearing properties, such as when the composite is exposed to compression and/or tension forces.

The CNT arrays or sheets can be coated with, dispersed within, infiltrated by, or filled in with PCMs selected from polymeric, non-polymeric, low melting temperature metal or metal alloys, or combinations thereof. In preferred embodiments, all or substantially all of the free volume or void space(s) between nanotubes is filled with the PCM. As used herein, “substantially all” refers to at least about 99.9%, 99%, 98%, 97%, 96%, or 95% filling of spaces, cavities, or void spaces present in the CNT array or sheet.

In another embodiment, the CNT arrays or sheets are dipped into PCM containing solutions or dispersions or directly into melted PCM to coat CNTs throughout and infiltrate the CNT array via capillary action in order to fill all or substantially all of the air and/or free volume or void space present between tubes in the array. In certain embodiments, PCM coated and/or filled CNT arrays or sheets are then placed between a chip and heat sink or heat spreader with the application of solvent or heat to reflow the PCM and bond the CNT sheet between the chip and heat sink or spreader to reduce the thermal resistance between the chip and heat sink or heat spreader.

In yet other embodiments, the PCM material can be deposited on the CNT array or sheet using deposition techniques known in the art, such as chemical deposition (e.g., chemical vapor deposition (CVD)), aerosol spray deposition, and electrochemical deposition.

In one embodiment, the polymer is applied by electrochemical deposition. In electrochemical deposition, the monomer of the polymer is dissolved in electrolyte and the CNT array or sheet is used as the working electrode, which is opposite the counter electrode. A potential is applied between the working and counter electrode with respect to a third reference electrode. The monomer is electrooxidized on the CNT array tips or sheet sidewalls that face the electrolyte as a result of the applied potential. Controlling the total time in which the potential is applied controls the thickness of the deposited PCM layer.

The PCM-CNT composites are typically bonded to a substrate, such as a metal (e.g., gold or aluminum foil). In some embodiments, CNTs formed on Si substrates can be bonded to metallic foils, such as Ag foil (e.g. 1×1 cm square, 25 μm thick). The Ag foil acts as a thermally conductive top substrate. Before bonding, a metallic layer (e.g. 80 nm of Ti) can be evaporated onto the topside of the metallic foil for absorbing the laser energy (λ=1100 nm). To bond the polymer coated CNT forests to the metallic foil, the CNT forests were first wet with a few droplets of solvent (e.g., CHCl₃) to reflow the coating, and then promptly placed into contact with the foil under pressure. The interface was allowed to dry, typically for several (e.g., 5) hours at ambient conditions before the load was removed.

In certain embodiments, multiple tiers of a single layer PCM-CNT-substrate composite may be stacked, as described (see FIGS. 1 and 3A) with metal substrates placed on top of one another. In some embodiments, when two or more tiers are stacked onto one another the interfacing PCM-CNT tiers may be interdigitated within one another, as shown in FIG. 3B.

The phase change material-carbon nanotube-substrate (PCM-CNT-substrate) composites include vertically aligned carbon nanotubes grown on and well-attached to a metal substrate and having a heat storing phase change material (PCM) infiltrated into the array (see FIG. 1). It is believed that the vertical alignment of the CNTs minimizes the problem of numerous thermal boundary resistances impeding heat transfer in the cross plane direction as heat is primarily conducted along the individual carbon nanotubes' axes, as opposed to across thousands of individual tubes. If the substrate onto which the carbon nanotubes are grown is a material of high thermal conductivity such as aluminum or aluminum composites, copper or copper composites, other high conductivity metals, thin film semiconductors or other highly conducting flexible substrates such as graphite, then the resistance to heat transfer in the in plane direction due to interfacial boundary resistances is also minimized as heat is efficiently carried in the in plane direction through the substrate. For purposes of thermal control, the phase change material should preferably have a melting temperature which is below the maximum allowable operating temperature of the heat generating device, such as an electronic device.

The PCM-CNT-substrate composite materials described can be placed in direct or indirect thermal contact or thermal communication with a heat generating device, such as an electronic device (see FIG. 2). In some embodiments, the composite material is in thermal communication with the device and the surrounding atmosphere thereby acting as a passive thermal control solution. Such contact/communication allows the device to store heat within the composite material in lieu of heating of the active heat generating device. The carbon nanotubes of the array present in the composite can efficiently reject and/or reflect heat to their surroundings via radiative processes.

In yet other embodiments, the composite material which is in thermal communication with the device is in further thermal communication with a secondary thermal solution, such as a heat sink, cold plate, heat spreader, or heat pipe to allow for regeneration of the PCM and/or allowing for continuous operation.

Preferably, the PCM of the composites is chosen such that it melts or solidifies at a temperature at or near the operating temperature of the heat generating device or at a temperature above the operating temperature of the heat generating device. When the temperature is above, the temperature chosen is preferably below the peak temperature which would be encountered during the manufacturing, packaging, or assembly of the heat generating device.

In preferred embodiments, the composite materials are flexible and/or conformable and can conform to one or more surfaces of the heat generating device. Flexibility allows for contouring the composite to fit the geometry of the device (i.e., conform to a 3-dimensional surface(s)) and allow for thermal communication with more than one heat generating surface on the device at a time. The PCM-CNT-substrates can be used for purposes of active thermal and/or passive thermal control management in such devices. Exemplary electronic devices include, but are not limited to, solid state electronics, microchips, power conversion devices, and radio frequency (RF) communication modules. In an embodiment, the heat generating device is a solid state electronics device such as a microchip, power conversion device, or RF communications module. In an embodiment, the phase change material is a polymer, such as natural or synthetic wax, plastics, or fatty acids. In another embodiment, the phase change material is a low meting temperature metal.

In one embodiment, the resistance to heat transfer between the composite and the heat generating device is reduced by placing the bottom surface of the composite in direct contact with the heat generating device. The high contact area of the PCM-CNT-substrate composite at this interface reduces the resistance to heat transfer between the heat generating device and the PCM composite without the need for any additional external thermal interface material.

The substrate of the described composites can be selected to be a high conductivity metal which enhances spreading in the composite. The substrate can also function as an extended surface area for purposes of heat transfer and thus can provide for more rapid regeneration of the phase change material during device operation. The substrate can also provide the composite with a higher in-plane thermal conductivity than a cross-plane thermal conductivity thereby allowing it to function as a heat spreader. In certain embodiments, the composite is in thermal communication with a device and the device may be operating in a continuous, intermittent, transient and/or limited manner. In other embodiments, the electronic device may be enhanced, even temporarily, to improve performance during high demand activities. In some embodiments, the composite, in part or in its entirety, may be encapsulated in a container, such as a solid container which allows for the composite to be readily installed, uninstalled, and/or reused. In one non-limiting embodiment, spreading in the PCM composite is enhanced by choosing a high thermal conductivity material as the encapsulating container.

The PCM-CNT-substrate composites can be formed and/or deposited, as required for a given particular application using known techniques. For example, in some instances only one surface (i.e., side) of the composite is anchored to a surface. In other cases, more than one surface (i.e., sides) of the composite may be anchored to a surface, such as of heat generating device(s).

The PCM-CNT-substrate composite materials may be placed or affixed in between a heat source and a heat sink, cold plate, heat spreader, such as between an integrated circuit package and a finned heat exchanger, or heat pipe to improve the transfer of heat from the heat source to the heat sink, cold plate, heat spreader, or heat pipe.

The PCM-CNT-substrate composites described exhibit both high thermal conductance and mechanical durability. As a consequence, these composites are well suited for applications where repeated cycling is required.

The PCM-CNT-substrates can be also be used as active thermal and/or passive thermal control applications including, but not limited, to areas such as personal computers, server computers, memory modules, graphics chips, radar and radio-frequency (RF) devices, disc drives, displays, including light-emitting diode (LED) displays, lighting systems, automotive control units, power-electronics, solar cells, batteries, communications equipment, such as cellular phones, thermoelectric generators, and imaging equipment, including Mills.

### BRIEF DESCRIPTION OF THE DRAWINGS

FIG. 1 is a non-limiting illustration of phase change material-carbon nanotube-metal substrate composite.

FIG. 2 is a non-limiting illustration of phase change material-carbon nanotube-metal substrate composite in thermal communication with a heat generating device.

FIGS. 3A and 3B depict non-limiting illustrations of stacked phase change material-carbon nanotube-metal substrate composites. FIG. 3A shows two (2) PCM-CNT-metal foil composites stacked atop one another. FIG. 3B shows two (2) PCM-CNT-metal foil composites stacked atop one another wherein the carbon nanotubes of the interfacing layers are interdigitated.

FIG. 4 is a line graph of the maximum chip temperature (° C., y-axis) versus time (min, x-axis) for octacore mobile device processors having thereon a commercial aluminum heat sink, a bare die, and a stacked composite as described herein.

FIG. 5 is a bar graph of an Android benchmark score (y-axis) and the scores for an octacore mobile device processor having thereon a commercial aluminum (full) heat sink thereon, a bare die, and a stacked composite as described herein.

FIG. 6 is a non-limiting illustration of a wireless charging battery (i.e., phone battery) having a PCM-CNT-substrate composite material thereon which provides electromagnetic interference shielding and passive heat dissipation.

FIG. 7 is a non-limiting illustration of a printed circuit board (PCB) having passive components and a heat generating component and having a PCM-CNT-substrate composite material thereon which provides electromagnetic interference shielding and passive heat dissipation.

### DETAILED DESCRIPTION OF THE INVENTION

### I. Definitions

“Carbon Nanotube Array” or “CNT array” or “CNT forest”, as used herein, refers to a plurality of carbon nanotubes which are vertically aligned on a surface of a material. Carbon nanotubes are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

“Carbon Nanotube Sheet” or “CNT sheet”, as used herein, refers to a plurality of carbon nanotubes which are aligned in plane to create a free-standing sheet. Carbon nanotubes are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

### II. Carbon Nanotube Arrays and Sheets

A. Carbon Nanotube Arrays

Carbon nanotube arrays are described herein. The arrays contain a plurality of carbon nanotubes supported on, or attached to, the surface of an inert substrate, such as a metallic (e.g., Al or Au) foil, silicon, or the surface of a heat sink or spreader. The CNT arrays can be formed using the methods described below. The CNTs are vertically aligned on the substrate. CNTs are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

Generally, the nanotubes are present at a sufficient density such that the nanotubes are self-supporting and adopt a substantially perpendicular orientation to the surface of the multilayer substrate. Preferably, the nanotubes are spaced at optimal distances from one another and are of uniform height to minimize thermal transfer losses, thereby maximizing their collective thermal diffusivity.

The CNT arrays contain nanotubes which are continuous from the top of the array (i.e., the surface formed by the distal end of the carbon nanotubes when vertically aligned on the multilayer substrate) to bottom of the array (i.e., the surface of the multilayer substrate). The array may be formed from multi-wall carbon nanotubes (MWNTs), which generally refers to nanotubes having between approximately 4 and approximately 10 walls. The array may also be formed from few-wall nanotubes (FWNTs), which generally refers to nanotubes containing approximately 1-3 walls. FWNTs include single-wall carbon nanotubes (SWNTs), double-wall carbon nanotubes (DWNTS), and triple-wall carbon nanotubes (TWNTs). In certain embodiments, the nanotubes are MWNTs. In some embodiments, the diameter of MWNTs in the arrays ranges from 10 to 40 nm, more preferably 15 to 30 nm, most preferably about 20 nm. The length of MWNTs in the arrays can range from 1 to 5,000 micrometers, preferably 5 to 5000 micrometers, preferably 5 to 2500 micrometers, more preferably 5 to 2000 micrometers, more preferably 5 to 1000 micrometers.

The CNTs display strong adhesion to the substrate. In certain embodiments, the CNT array or sheet will remain substantially intact after being immersed in a solvent, such as ethanol, and sonicated for a period of at least five minutes. In particular embodiments, at least about 90%, 95%, 96%, 97%, 98%, 99%, or 99.9% of the CNTs remain on the surface after sonication in ethanol.

B. Carbon Nanotube Sheets

Carbon nanotube sheets are also. The sheets contain a plurality of carbon nanotubes that support each other through strong van der Waals force interactions and mechanical entanglement to form a freestanding material. The CNT sheets can be formed using the methods described below. The CNTs form a freestanding sheet and are aligned in plane with the surface of this sheet. CNTs are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

Generally, the nanotubes are present at a sufficient density such that the nanotubes are self-supporting and adopt a substantially parallel orientation to the surface of the sheet. Preferably, the nanotubes are spaced at optimal distances from one another and are of uniform length to minimize thermal transfer losses, thereby maximizing their collective thermal diffusivity.

The CNT sheets may be formed from multi-wall carbon nanotubes (MWNTs), which generally refers to nanotubes having between approximately 4 and approximately 10 walls. The sheets may also be formed from few-wall nanotubes (FWNTs), which generally refers to nanotubes containing approximately 1-3 walls. FWNTs include single-wall carbon nanotubes (SWNTs), double-wall carbon nanotubes (DWNTS), and triple-wall carbon nanotubes (TWNTs). In certain embodiments, the nanotubes are MWNTs. In some embodiments, the diameter of MWNTs in the arrays ranges from 10 to 40 nm, more preferably 15 to 30 nm, most preferably about 20 nm. The length of MWNTs in the sheets can range from 1 to 5,000 micrometers, preferably 100 to 5000 micrometers, preferably 500 to 5000 micrometers, more preferably 1000 to 5000 micrometers.

C. Supports

A variety of materials can serve as substrates or supports for the PCM-CNT composites.

Generally, the substrate or support is formed at least in part from a metal, such as aluminum, cobalt, chromium, zinc, tantalum, platinum, gold, nickel, iron, tin, lead, silver, titanium, indium, copper, or combinations thereof and/or one or more metal oxides, such as oxides of the metals listed above. Other materials can include, but are not limited to, ceramics, graphite, graphitic materials and silicon or silicon compounds, such as silicon dioxide.

In some instances, the support is a readily deformable and/or flexible sheet of solid material. In certain embodiments, the support is a metallic foil, such as aluminum foil or copper foil.

The support may also be a surface of a device, such as a conventional heat sink or heat spreader used in heat exchange applications. Such heat sinks may be formed from a variety of materials including copper, aluminum, copper-tungsten pseudoalloy, AlSiC (silicon carbide in an aluminum matrix), Dymalloy (diamond in copper-silver alloy matrix), and E-Material (beryllium oxide in beryllium matrix).

In some embodiments, the surface of the support may be treated to increase adhesion with the adhesion layer. Such treatment may include the use of plasma-assisted or chemical-based surface cleaning. Another treatment would include the deposition of a metal or metal oxide coating or particles on the support.

Multilayer substrates can be formed on one or more surfaces of a suitable support. For example, in certain embodiments, the support is a metallic foil. In these instances, multilayer substrates can be formed on one or both sides of the metallic foil as required for a particular application.

The support, and conditions under which the CNTs are formed, should be selected such that the support resists reacting with the catalyst, process gases, and/or residual gases through reactions, such as oxidation, silicidation, alloying, and/or carbide formation. For example, C, O, H, and N are the elements composing most CNT CVD process and contamination gases. Under certain conditions, the support can react to form oxides, carbides, and other byproducts which significantly reduce CNT growth which in turn leads to loss of electrical conduction in the support. Reaction conditions, such as temperature, can be selected in order to minimize adverse reactions of the support.

D. Phase Change Materials (PCM)

The array or sheet of nanotubes are coated with, dispersed within, infiltrated by, or filled with a phase change material(s) (PCMs). The PCM material(s) acts as a thermal storage medium capable of storing heat energy. The PCM can be applied as described below. In some embodiments, the PCM is or contains one or more oligomeric materials, polymeric materials, or combinations thereof. In other embodiments, the PCM is or contains one or more non-polymeric materials. In some embodiments, the PCM is or contains a mixture of oligomeric and/or polymeric material and non-polymeric materials. In yet other embodiments, the PCM is or contains a low melting temperature metal.

A variety of PCM materials can be used to coat the CNT arrays or sheets or fill the space(s) between the nanotubes of the arrays or sheets. In preferred embodiments, the PCM can fill all or substantially all of the free volume or void space(s) between nanotubes. As used herein, “essentially all” refers to at least about 99.9%, 99%, 98%, 97%, 96%, or 95% filling of spaces, cavities, or void spaces present in the CNT array or sheet.

In particular embodiments, the PCM can cause a decrease in the thermal resistance of the array or sheet. PCM materials can be applied in liquid or powder spray form to conformally coat the tips or sidewalls of the CNTs or to fill in the free volume (i.e., between tubes) present in a CNT array or sheet. “Conformally,” as used herein generally refers to a uniform coating that is pin-hole free or substantially pin-hole free (i.e., having less than 10%, 9%, 8%, 7%, 6%, 5%, 4%, 3%, 2%, 1% pin-holes), on the tips and/or side-walls of the vertically aligned CNTs. Conformal coatings may be less than about 30 nm, 25 nm, 20 nm, 15 nm, 10 nm, 9 nm, 8 nm, 7 nm, 6 nm, 5 nm, 4 nm, 3 nm, 2 nm, or 1 nm in thickness. The conformal coating may have a thickness of between about 1 nm to 5,000 nm, 1 nm to 2,500 nm, 1 nm to 1,000 nm, 1 nm to 500 nm, 1 nm to 250 nm, 1 nm to 100 nm, or 1 nm to 50 nm. It is also desirable that the PCM material be reflowable as the interface is assembled using, for example, solvent, heat or some other easy to apply source. The PCM must be thermally stable up to at least about 120° C., 130° C., 140° C., 150° C., 160° C., 170° C., 180° C., 190° C., 200° C. In some embodiments, the coating can be readily removable, such as by heat or dissolution in a solvent, to allow for “reworking” of the PCM. “Reworking”, as used herein, refers to breaking the PCM (i.e., removing the coating) by applying solvent or heat in order to clean or remove the PCM for application of a new PCM.

1. Polymeric PCMs

In some embodiments, the PCM is, or contains, one or more polymeric materials. The PCM can contain a conjugated polymer, such as an aromatic, heteroaromatic, or non-aromatic polymer, or a non-conjugated polymer.

Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic, conjugated polymers include, but are not limited to, polyacetylenes and polydiacetylenes. The polymer classes listed above include substituted polymers, wherein the polymer backbone is substituted with one or more functional groups, such as alkyl groups. In some embodiments, the polymer is polystyrene (PS). In other embodiments, the polymer is poly(3-hexythiophene) (P3HT). In other embodiments, the polymer is poly(3,4-3thylenedioxythiophene) (PEDOT) or poly(3,4-3thylenedioxythiophene) poly(styrenesulfonate) (PEDOT:PSS).

In other embodiments, the polymer is a non-conjugated polymer. Suitable non-conjugated include, but are not limited to, polyvinyl alcohols (PVA), poly(methyl methacrylates) (PMMA), polydimethylsiloxanes (PDMS), and combinations (blends) thereof. In other embodiments, the polymer is a paraffin wax. In some embodiments, the polymer is a natural wax or fatty acid. In other embodiments, the polymer is a synthetic wax such as Fischer-Tropsch waxes or polyethylene waxes. In other embodiments, the polymer is a wax that has a melting temperature above about 80, 90, 100, 110, or 120° C., preferably above 130° C. In other embodiments, the polymer is a hot glue or hot melt adhesive that combines wax, tackifiers and a polymer base to provide improved surface adhesion.

In other embodiments, the PCM is one or more polymers which are adhesives, such as pressure sensitive adhesives. In yet other embodiments, the PCM polymers are selected from thermoplastic adhesives which can be conformally coated on all or part of the CNT arrays or sheets and which preferably add no additional thermal resistance. “Conformally,” as used herein generally refers to a uniform coating that is pin-hole free or substantially pin-hole free (i.e., having less than 10%, 9%, 8%, 7%, 6%, 5%, 4%, 3%, 2%, 1% pin-holes), on the tips and/or side-walls of the vertically aligned CNTs. Conformal coatings may be less than about 30 nm, 25 nm, 20 nm, 15 nm, 10 nm, 9 nm, 8 nm, 7 nm, 6 nm, 5 nm, 4 nm, 3 nm, 2 nm, or 1 nm in thickness. The conformal coating may have a thickness of between about 1 nm to 5,000 nm, 1 nm to 2,500 nm, 1 nm to 1,000 nm, 1 nm to 500 nm, 1 nm to 250 nm, 1 nm to 100 nm, or 1 nm to 50 nm. Exemplary adhesives which may be used as PCMs include but are not limited to polyurethanes, nylons, styrenic block copolymers, olefins, poly(olefins), thermoplastic vulcanizates, polyesters, copolyesters, polyamides, and combinations thereof. The polymer-based adhesives may have any suitable weight average molecular weight. In some instances the weight average molecular weight of the polymer-based adhesives used as PCMs are in the range of between 1,000 to 1,000,000 Da, 1,000 to 500,000 Da, 1,000 to 100,000 Da, 1,000 to 75,000 Da, 1,000 to 50,000 Da, or 1,000 to 25,000 Da.

2. Low Melting Metal PCMs

The CNT arrays or sheets can be dispersed within, or filled in with a low melting temperature metal or metal alloys or combinations thereof. The one or more metals may be applied to the CNT arrays or sheets using any known technique. The one or more metals can be adsorbed to the distal ends and/or sidewalls of the CNTs to bond the distal ends and/or sidewalls of the CNTs to a surface, reduce thermal resistance between the CNT array or sheet and a surface, or combinations thereof.

Examples of suitable low melting temperature metals include, but are not limited to, bismuth, indium, tin, gallium, and combinations thereof.

In other embodiments, the CNT arrays or sheets can additionally be coated with one or more metal nanoparticles. One or more metal nanoparticles may be adsorbed to the distal ends and/or sidewalls of the CNTs to bond the distal ends of the CNTs to a surface, reduce thermal resistance between the CNT array or sheet and a surface, or combinations thereof. Metal nanoparticles can be applied to CNT arrays or sheets using a variety of methods known in the art. For example, electron-beam or sputter deposition can be used to coat metal nanoparticles or connected “film-like” assemblies of nanoparticles onto the distal ends and/or sidewalls of the CNTs. The metallic particles can be coated simultaneously with the coating or before or after coating.

E. Reduction in Thermal Resistance

The PCM-CNT array or sheet composites exhibit reduced thermal resistance compared to uncoated or unfilled arrays or sheets.

In one embodiment, the thermal resistance of the PCM-CNT array or sheet composites is reduced by at least about 25%, 30%, 35%, 40%, 45%, 50%, 55%, 60%, 65%, 70% or greater compared to uncoated and/or unfilled CNT arrays or sheets when measured using the photoacoustic method. This reduction is observed for one-sided and two-sided arrays and for sheets coated on one or both side. In other embodiments, the coated arrays exhibit thermal resistances less than about 5.0, 4.5, 4.0, 3.5, 3.0, 2.5, 2.0, 1.5 mm²K/W. In some embodiments, the thermal resistance is about 2, preferably about 1 mm²K/W.

PCM coated or filled CNT arrays or sheets can exhibit increased shear attachment strength, as compared to uncoated and/or unfilled arrays or sheets. In some embodiments, the coated CNT arrays exhibit at least 1.5, 2.0, 2.5, or 3.0-fold or greater increase in the shear attachment strength to glass to uncoated or unfilled arrays or sheets when bonded to glass slides. It is believed that the presence of a PCM, such as a polymer, may increase the contact area by engaging additional CNTs, especially since capillary forces associated with drying of solvent during the bonding process likely draw additional CNT tips closer to the interface.

### III. Methods for Preparing PCM-Carbon Nanotube—Substrate Composites

A. Carbon Nanotube Arrays

Carbon nanotube arrays can be prepared using techniques well known in the art. In one embodiment, the arrays are prepared as described in U.S. Ser. No. 13/356,827. This method involves the use of multilayer substrates to promote the growth of dense vertically aligned CNT arrays and provide excellent adhesion between the CNTs and metal surfaces.

Generally, the support or substrate onto which the CNT arrays or sheets are formed at least in part from a metal, such as aluminum, platinum, gold, nickel, iron, tin, lead, silver, titanium, indium, copper, or combinations thereof. In certain instances, the support is a metallic foil, such as aluminum or copper foil. The support may also be a surface of a device, such as a conventional heat sink or heat spreader used in heat exchange applications.

The support or substrate onto which the CNT arrays or sheets are formed may also include an adhesion layer is formed of a material that improves the adhesion of the interface layer to the support. In certain embodiments, the adhesion layer is a thin film of iron. Generally, the adhesion layer must be thick enough to remain a continuous film at the elevated temperatures used to form CNTs. The adhesion layer also generally provides resistance to oxide and carbide formation during CNT synthesis at elevated temperatures.

The support or substrate onto which the CNT arrays or sheets are formed may further include interface layer is preferably formed from a metal which is oxidized under conditions of nanotube synthesis or during exposure to air after nanotube synthesis to form a suitable metal oxide. Examples of suitable materials include aluminum. Alternatively, the interface layer may be formed from a metal oxide, such as aluminum oxide or silicon oxide. Generally, the interface layer is thin enough to allow the catalytic layer and the adhesion layer to diffuse across it. In some embodiments wherein the catalytic layer and the adhesion layer have the same composition, this reduces migration of the catalyst into the interface layer, improving the lifetime of the catalyst during nanotube growth.

The support or substrate onto which the CNT arrays or sheets are formed can include a catalytic layer, which is typically a thin film formed from a transition metal that can catalyze the formation of carbon nanotubes via chemical vapor deposition. Examples of suitable materials that can be used to form the catalytic layer include iron, nickel, cobalt, rhodium, palladium, and combinations thereof. In some embodiments, the catalytic layer is formed of iron. The catalytic layer is of appropriate thickness to form catalytic nanoparticles or aggregates under the annealing conditions used during nanotube formation.

In other embodiments, the substrate or support serves as catalytic surface for the growth of a CNT array. In these instances, the process of CNT growth using chemical vapor deposition alters the morphology of the multilayer substrate. Specifically, upon heating, the interface layer is converted to a metal oxide, and forms a layer or partial layer of metal oxide nanoparticles or aggregates deposited on the adhesion layer. The catalytic layer similarly forms a series of catalytic nanoparticles or aggregates deposited on the metal oxide nanoparticles or aggregates. During CNT growth, CNTs form from the catalytic nanoparticles or aggregates. The resulting CNT arrays contain CNTs anchored to an inert support via an adhesion layer, metal oxide nanoparticles or aggregates, and/or catalytic nanoparticles or aggregates.

In some embodiments, the CNT arrays or sheets are formed by vertically aligning a plurality of CNTs on the multilayer substrate described above. This can be accomplished, for example, by transferring an array of CNTs to the distal ends of CNTs grown on the multilayer substrate. In some embodiments, tall CNT arrays are transferred to the distal ends of very short CNTs on the multilayer substrate. This technique improves the bond strength by increasing the surface area for bonding.

The inert support for the CNT array or sheet can be a piece of metal foil, such as aluminum foil. In these cases, CNTs are anchored to a surface of the metal foil via an adhesion layer, metal oxide nanoparticles or aggregates, and catalytic nanoparticles or aggregates. In some instances only one surface (i.e., side) of the metal foil contains an array or sheet of aligned CNTs anchored to the surface. In other cases, both surfaces (i.e., sides) of the metal foil contain an array or sheet of aligned CNTs anchored to the surface. In other embodiments, the inert support for the CNT array or sheet is a surface of a conventional metal heat sink or heat spreader. In these cases, CNTs are anchored to a surface of the heat sink or heat spreader via an adhesion layer, metal oxide nanoparticles or aggregates, and catalytic nanoparticles or aggregates. This functionalized heat sink or heat spreader may then be abutted or adhered to a heat source, such as an integrated circuit package.

B. Carbon Nanotube Sheets

Carbon nanotube sheets can be prepared using techniques well known in the art. In one embodiment, the sheets are prepared as described in U.S. Pat. No. 7,993,620 B2. In this embodiment, CNT agglomerates are collected into sheets in-situ inside the growth chamber on metal foil substrates. The sheets can then be densified by removing the solvent. In another embodiment, the CNT sheets are made by vacuum filtration of CNT agglomerates that are dispersed in a solvent.

C. PCM-Carbon Nanotube Array and Sheets Composites

1. Phase Change Material Infiltration

Flowable or phase change materials, as described above, may be applied to the CNT array or sheet to displace the air or other void space or volume space present between CNTs and improve contact between the distal ends and/or sidewalls of CNTs and a surface, and as a result reduce thermal resistance of the array or sheet and the contact between the array or sheet and a surface, or combinations thereof. In related embodiments, the PCM can further provide structural integrity to the vertically aligned CNT array or sheet. Flowable or phase change materials can be applied to CNT arrays using a variety of methods known in the art.

In one embodiment, the phase change material wets the CNTs and infiltrates the CNT array via capillary action or wicking action. In an embodiment, the PCM is dissolved in a suitable solvent that allows it to easily infiltrate the array, followed by evaporation of the solvent. In another embodiment, the PCM is infiltrated into the array in the form of solid particulate form which may be polymeric, non-polymeric, metallic, or ceramic nanoparticles that are reflowed and agglomerated following infiltration. Preferably, the size of the solid particulates is chosen such that the average diameter is smaller than the nanotube-to-nanotube spacing distance with the array. In one embodiment, the PCM is infiltrated into the array via an in situ chemical reaction, such as electrodeposition.

In another embodiment, the phase change material is infiltrated into the array or sheet via application of a pressure gradient. In preferred embodiments, the pressure gradient that the array or sheet can sustain without collapse or delamination from the substrate is enhanced to due superior adhesion between the CNTs and the metal substrate. This superior adhesion may be quantified through the array's ability to endure mechanical agitation such as sonication, as discussed above. In such an embodiment, the CNT array can survive/withstand sonication in an ultrasonic bath in the presence of a solvent, signifying sufficient adhesion to survive pressure based infiltration methods for applying one or more PCMs thereto.

In yet another embodiment, the pressure gradient required for infiltration can be reduced by modifying the surface energy of the CNTs of the array or sheet through an applied coating, such as through application of polymeric, non-polymeric, or metallic nanoparticles, as described above. In one embodiment, the surface energy of the CNT array is modified through the introduction of one or more structural defects or non-carbon species into the nanotubes.

Examples of suitable flowable or phase change materials include, but is not limited to, fatty acids, natural waxes, paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some embodiments, the coating material, such as a non-polymeric coating material and the flowable or phase change material are the same material or materials.

The CNT arrays or sheets which are coated, dispersed by, or filled in with a PCM can be abutted or bonded to a thermally conducting substrate to prepare a device for evaluating thermal resistance or a heat source, such as an integrated circuit package, to form a commercial product. In some embodiments, the PCM can further impart adhesive properties to the composite on the metal substrate. The CNT array of the composite may also provide stress relief to the phase change material by providing structural reinforcement and load bearing properties, such as when the composite is exposed to compression and/or tension forces.

2. Phase Change Materials (PCMs)

The CNT arrays or sheets can be coated with, dispersed within, infiltrated by, or filled in with PCMs selected from polymeric, non-polymeric, low melting temperature metal or metal alloys, or combinations thereof. In preferred embodiments, all or substantially all of the free volume or void space(s) between nanotubes is filled with the PCM. As used herein, “substantially all” refers to at least about 99.9%, 99%, 98%, 97%, 96%, or 95% filling of spaces, cavities, or void spaces present in the CNT array or sheet.

PCMs can be dissolved in one or more solvents and spray coated or chemically or electrochemically deposited onto the CNT forests, arrays grown on a substrate, or on a sheet, as described above. The PCMs can also be spray coated in powder form onto the top of vertical CNT forests or arrays grown on a substrate, or on CNT sheets as described above. The PCMs can include polymers or metals that adhere or bond to CNTs through van der Waals bonds, π-π stacking, mechanical wrapping and/or covalent bonds and bond to metal, metal oxide, or semiconductor material surfaces through van der Waals bonds, π-π stacking, and/or covalent bonds.

For spray coating, solutions can be prepared by sonicating or stirring the one or more PCM materials for a suitable amount of time in an appropriate solvent. The solvent is typically an organic solvent or solvent and should be a solvent that is easily removed, for example by evaporation at room temperature or elevated temperature. Suitable solvents include, but are not limited to, chloroform or other suitable organic solvents. The polymer can also be spray coated in dry form using powders with micron scale particle sizes, i.e., particles with diameters less than about 100, 75, 50, 40, 30, 20, 10, 5 or 1 micrometers. In this embodiment, the polymer powder would need to be soaked with solvent or heated into a liquid melt to spread the powder particles into a more continuous coating after they are spray deposited.

The thickness of the PCM, when formed as coatings on the CNTs, is generally between 1 and 5000 nm, preferably between 1 and 500 nm, more preferably between 1 and 100 nm, most preferably between 1 and 50 nm. In some embodiments, the coating thickness is less than 500, 450, 400, 350, 300, 250, 200, 150, 100, 90, 80, 70, 60, 50, 40, 30, 20 or 10 nm.

Spray coating process restricts the deposition of coating to the CNT tips and limits clumping due to capillary forces associated with the drying of the solvent. The amount of coating visible on the CNT arrays increases with the number of sprays. No morphological differences were observable between PS and P3HT as shown in the examples. Alternative techniques can be used to spray coat the coating materials onto the CNT arrays including techniques more suitable for coating on a commercial scale.

In another embodiment, the CNT arrays or sheets are dipped into PCM containing solutions or dispersions or directly into melted PCM to coat CNTs throughout and infiltrate the CNT array via capillary action in order to fill all or substantially all of the air and/or free volume or void space present between tubes in the array. In certain embodiments, PCM coated and/or filled CNT arrays or sheets are then placed between a chip and heat sink or heat spreader with the application of solvent or heat to reflow the PCM and bond the CNT sheet between the chip and heat sink or spreader to reduce the thermal resistance between the chip and heat sink or heat spreader.

In yet other embodiments, the PCM material can be deposited on the CNT array or sheet using deposition techniques known in the art, such as chemical deposition (e.g., chemical vapor deposition (CVD)), aerosol spray deposition, and electrochemical deposition.

In one embodiment, the polymer is applied by electrochemical deposition. In electrochemical deposition, the monomer of the polymer is dissolved in electrolyte and the CNT array or sheet is used as the working electrode, which is opposite the counter electrode. A potential is applied between the working and counter electrode with respect to a third reference electrode. The monomer is electrooxidized on the CNT array tips or sheet sidewalls that face the electrolyte as a result of the applied potential. Controlling the total time in which the potential is applied controls the thickness of the deposited PCM layer.

The PCM-CNT composites are typically bonded to a substrate, such as a metal (e.g., gold or aluminum foil). In some embodiments, CNTs formed on Si substrates can be bonded to metallic foils, such as Ag foil (e.g. 1×1 cm square, 25 μm thick). The Ag foil acts as a thermally conductive top substrate. Before bonding, a metallic layer (e.g. 80 nm of Ti) can be evaporated onto the topside of the metallic foil for absorbing the laser energy (λ=1100 nm). To bond the polymer coated CNT forests to the metallic foil, the CNT forests were first wet with a few droplets of solvent (e.g., CHCl₃) to reflow the coating, and then promptly placed into contact with the foil under pressure. The interface was allowed to dry, typically for several (e.g., 5) hours at ambient conditions before the load was removed.

3. Polymeric PCMs

In some embodiments, the PCM material is, or contains, one or more oligomeric and/or polymeric materials. In particular embodiments, the polymer can be a conjugated polymer, including aromatic and non-aromatic conjugated polymers. Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic polymers include, but are not limited to, polyacetylenes and polydiacetylenes. The polymer classes listed above include substituted polymers, wherein the polymer backbone is substituted with one or more functional groups, such as alkyl groups. In some embodiments, the polymer is polystyrene (PS). In other embodiments, the polymer is poly(3-hexythiophene) (P3HT). In yet other embodiments, the polymers are selected from polyurethanes, nylons, styrenic block copolymers, olefins, poly(olefins), thermoplastic vulcanizates, polyesters, copolyesters, polyamides, and combinations thereof.

In other embodiments, the polymer is a non-conjugated polymer. Suitable non-conjugated include, but are not limited to, polyvinyl alcohols (PVA), poly(methyl methacrylates) (PMMA), polydimethylsiloxanes (PDMS), and combinations (blends) thereof.

In other embodiments, the polymer is a natural wax, such as paraffin wax. In other embodiments, the polymer is a synthetic wax such as Fischer-Tropsch waxes or polyethylene waxes. In other embodiments, the polymer is a wax that has a melting temperature above 80, 90, 100, 110, and 120° C., preferably above 130° C. In other embodiments, the polymer is a hot glue or hot melt adhesive that combines wax, tackifiers and a polymer base to provide improved surface adhesion.

In other embodiments, the PCM is one or more polymers which are adhesives, such as pressure sensitive adhesives. In yet other embodiments, the PCM polymers are selected from thermoplastic adhesives which can be conformally coated on all or part of the CNT arrays or sheets and which preferably add no additional thermal resistance. “Conformally,” as used herein generally refers to a uniform coating that is pin-hole free or substantially pin-hole free (i.e., having less than 10%, 9%, 8%, 7%, 6%, 5%, 4%, 3%, 2%, 1% pin-holes), on the tips and/or side-walls of the vertically aligned CNTs. Conformal coatings may be less than about 30 nm, 25 nm, 20 nm, 15 nm, 10 nm, 9 nm, 8 nm, 7 nm, 6 nm, 5 nm, 4 nm, 3 nm, 2 nm, or 1 nm in thickness. The conformal coating may have a thickness of between about 1 nm to 5,000 nm, 1 nm to 2,500 nm, 1 nm to 1,000 nm, 1 nm to 500 nm, 1 nm to 250 nm, 1 nm to 100 nm, or 1 nm to 50 nm. Exemplary adhesives which may be used as PCMs include but are not limited to polyurethanes, nylons, styrenic block copolymers, olefins, poly(olefins), thermoplastic vulcanizates, polyesters, copolyesters, polyamides, and combinations thereof. The polymer-based adhesives may have any suitable weight average molecular weight. In some instances the weight average molecular weight of the polymer-based adhesives used as PCMs are in the range of between 1,000 to 1,000,000 Da, 1,000 to 500,000 Da, 1,000 to 100,000 Da, 1,000 to 75,000 Da, 1,000 to 50,000 Da, or 1,000 to 25,000 Da.

4. Low Melting Metal and Ceramic PCMs

The CNT arrays or sheets can be coated with, dispersed within, infiltrated by, or filled in with a low melting temperature metal or metal alloys or combinations thereof. The one or more metals may be applied to the CNT arrays or sheets using any known technique. The one or more metals can be adsorbed to the distal ends and/or sidewalls of the CNTs to bond the distal ends and/or sidewalls of the CNTs to a surface, reduce thermal resistance between the CNT array or sheet and a surface, or combinations thereof.

Examples of suitable low melting temperature metals include, but are not limited to, bismuth, indium, tin, gallium, and combinations thereof.

In other embodiments, the CNT arrays or sheets can additionally be coated with one or more metal nanoparticles. One or more metal nanoparticles may be adsorbed to the distal ends and/or sidewalls of the CNTs to bond the distal ends of the CNTs to a surface, reduce thermal resistance between the CNT array or sheet and a surface, or combinations thereof. Metal nanoparticles can be applied to CNT arrays or sheets using a variety of methods known in the art. For example, electron-beam or sputter deposition can be used to coat metal nanoparticles or connected “film-like” assemblies of nanoparticles onto the distal ends and/or sidewalls of the CNTs. The metallic particles can be coated simultaneously with the coating or before or after coating.

In some embodiments, the CNT array or sheet may be modified with a metal, metal alloy, metallic nanoparticles, and/or ceramics prior to application of the PCM to modify the surface energy of the vertically aligned CNT array in order to modify or improve the wetting properties of the phase change.

5. Stacked PCM-CNT-Substrate Composites

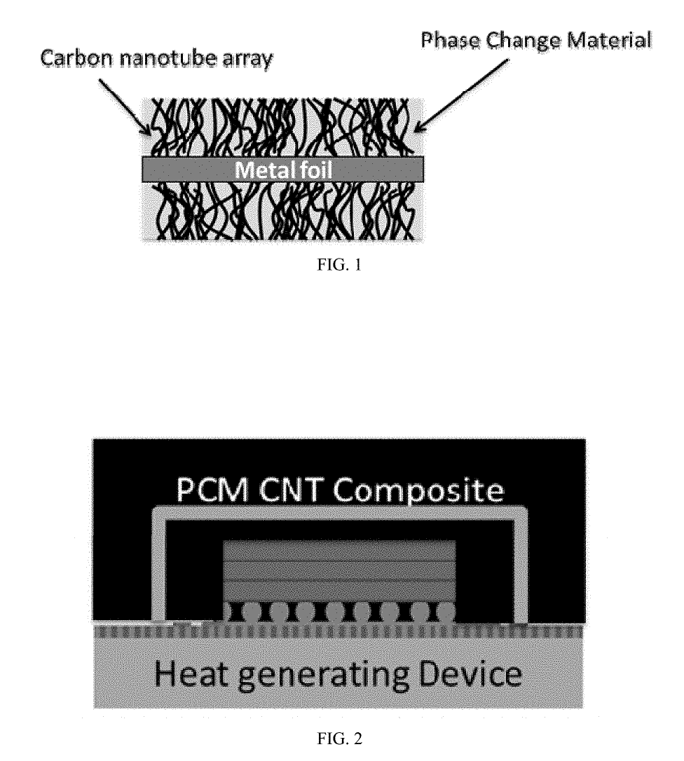

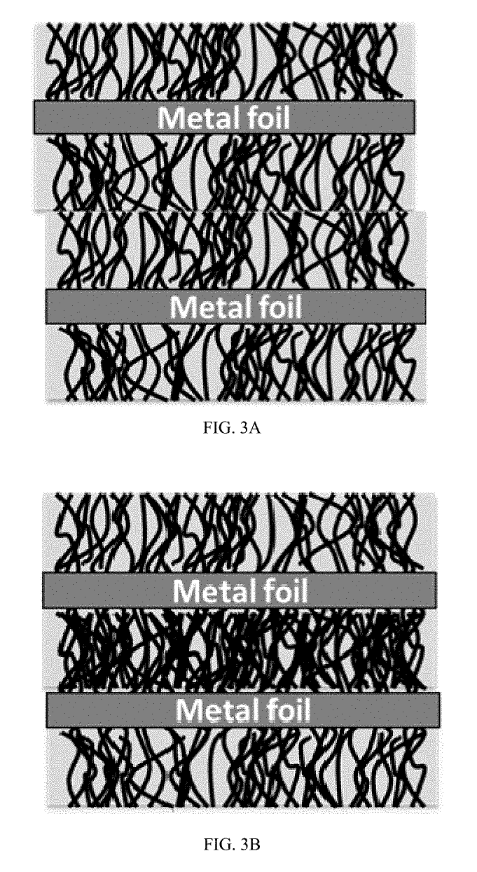

Due to various fundamental and practical factors, such as diffusion of the catalyst material, required growth times, and growth temperatures, the length that the CNTs of the arrays or sheets may be grown could be limited to tens of micrometers up to tens of millimeters, depending on the processing conditions. This can place an upper limit on the thickness of the PCM-CNT-substrate composite, and as such, the total heat storage capacity of the material. Accordingly, in certain embodiments, this limitation is overcome by stacking multiple tiers of the single layer PCM-CNT-substrate composites described (see FIGS. 1 and 3A) with metal substrates on top of one another.

In some embodiments, when two or more tiers are stacked onto one another the interfacing PCM-CNT tiers may be interdigitated within one another, as shown in FIG. 3B. The number of tiers of composites in a stack, without limitation, can be 2, 3, 4, 5, 6, 7, 8, 9, 10, 11, 12, 13, 14, 15, 16, 17, 18, 19, 20, 21, 22, 23, 24, 25, or more. The extent or degree of interdigitation between interfacing tiers may be essentially complete (˜100%) or at least about 5%, 10%, 20%, 30%, 40%, 50%, 60%, 70%, 75%, 80%, 85%, 90%, 95%, 96%, 97%, 98%, 99%, or 99.9%, as determined by the thickness of the stacked PCM-CNT composite under no load. The interdigitation may occur due to the application of pressure while the PCM is in a liquid state.

In some embodiments, the phase change material-carbon nanotube-substrate (PCM-CNT-substrate) composites described herein may be further coated with adhesives. Such adhesives can include one or more polymers including, but not limited to, polyurethanes, nylons, styrenic block copolymers, olefins, poly(olefins), thermoplastic vulcanizates, polyesters, copolyesters, polyamides, and combinations thereof. The polymer-based adhesives may have any suitable weight average molecular weight. In some instances the weight average molecular weight of the polymer-based adhesives used as PCMs are in the range of between 1,000 to 1,000,000 Da, 1,000 to 500,000 Da, 1,000 to 100,000 Da, 1,000 to 75,000 Da, 1,000 to 50,000 Da, or 1,000 to 25,000 Da.

The adhesive coating on the composite+may be optionally covered by a release liner to provide a peel-and-stick composite.

### IV. PCM-CNT-Substrate Composite Material Applications

The phase change material-carbon nanotube-substrate (PCM-CNT-substrate) composites include vertically aligned carbon nanotubes grown on and well-attached to a metal substrate and having a heat storing phase change material (PCM) infiltrated into the array (see FIG. 1). It is believed that the vertical alignment of the CNTs minimizes the problem of numerous thermal boundary resistances impeding heat transfer in the cross plane direction as heat is primarily conducted along the individual carbon nanotubes' axes, as opposed to across thousands of individual tubes. If the substrate onto which the carbon nanotubes are grown is a material of high thermal conductivity such as aluminum or aluminum composites, copper or copper composites, other high conductivity metals, thin film semiconductors or other highly conducting flexible substrates such as graphite, then the resistance to heat transfer in the in plane direction due to interfacial boundary resistances is also minimized as heat is efficiently carried in the in plane direction through the substrate. For purposes of thermal control, the phase change material should preferably have a melting temperature which is below the maximum allowable operating temperature of the heat generating device, such as an electronic device.

The PCM-CNT-substrate composite materials described can be placed in direct or indirect thermal contact or thermal communication with a heat generating source, wherein the source can be a device, such as an electronic device (see FIG. 2). In some embodiments, the composite material is in thermal communication with the source and the surrounding atmosphere thereby acting as a passive thermal control solution. Such contact/communication allows the device to store heat within the composite material in lieu of heating of the active heat generating device. Accordingly, the PCM material can act as a thermal storage medium capable of storing heat energy generated by the heat generating source. The carbon nanotubes of the array present in the composite can also efficiently reject and/or reflect heat to their surroundings via radiative processes.

In yet other embodiments, the composite material which is in thermal communication with the device is in further thermal communication with a secondary thermal solution, such as a heat sink, cold plate, heat spreader, or heat pipe to allow for regeneration of the PCM and/or allowing for continuous operation.

Preferably, the PCM of the composites is chosen such that it melts or solidifies at a temperature at or near the operating temperature of the heat generating device or at a temperature above the operating temperature of the heat generating device. When the temperature is above, the temperature chosen is preferably below the peak temperature which would be encountered during the manufacturing, packaging, or assembly of the heat generating device.

In preferred embodiments, the composite materials are flexible and/or conformable and can conform to one or more surfaces of the heat generating device. Flexibility allows for contouring the composite to fit the geometry of the device (i.e., conform to a 3-dimensional surface(s)) and allow for thermal communication with more than one heat generating surface on the device at a time. The PCM-CNT-substrates can be used for purposes of active thermal and/or passive thermal control management in such devices. Exemplary electronic devices include, but are not limited to, solid state electronics, microchips, power conversion devices, and radio frequency (RF) communication modules. In an embodiment, the heat generating device is a solid state electronics device such as a microchip, power conversion device, or RF communications module. In an embodiment, the phase change material is selected from a polymer, such as natural or synthetic wax, plastics, or fatty acids, amongst other materials. In another embodiment, the phase change material is a low meting temperature metal.

In one embodiment, the resistance to heat transfer between the composite and the heat generating device is reduced by placing the bottom surface of the composite in direct contact with the heat generating device. The high contact area of the PCM-CNT-substrate composite at this interface reduces the resistance to heat transfer between the heat generating device and the PCM composite without the need for any additional external thermal interface material.

The substrate of the described composites can be selected to be a high conductivity metal which enhances spreading in the composite. The substrate can also function as an extended surface area for purposes of heat transfer and thus can provide for more rapid regeneration of the phase change material during device operation. The substrate can also provide the composite with a higher in-plane thermal conductivity than a cross-plane thermal conductivity thereby allowing it to function as a heat spreader. In certain embodiments, the composite is in thermal communication with a device and the device may be operating in a continuous, intermittent, transient and/or limited manner. In other embodiments, the electronic device may be enhanced, even temporarily, to improve performance during high demand activities. In some embodiments, the composite, in part or in its entirety, may be encapsulated in a container, such as a solid container which allows for the composite to be readily installed, uninstalled, and/or reused. In one non-limiting embodiment, spreading in the PCM composite is enhanced by choosing a high thermal conductivity material as the encapsulating container.

The PCM-CNT-substrate composites can be formed and/or deposited, as required for a given particular application using known techniques. For example, in some instances only one surface (i.e., side) of the composite is anchored to a surface. In other cases, more than one surface (i.e., sides) of the composite may be anchored to a surface, such as of heat generating device(s).

The PCM-CNT-substrate composite materials may be placed or affixed in between a heat source and a heat sink, cold plate, heat spreader, such as between an integrated circuit package and a finned heat exchanger, or heat pipe to improve the transfer of heat from the heat source to the heat sink, cold plate, heat spreader, or heat pipe.

The PCM-CNT-substrate composites described exhibit both high thermal conductance and mechanical durability. As a consequence, these composites are well suited for applications where repeated cycling is required.

The PCM-CNT-substrates can be also be used as active thermal and/or passive thermal control applications including, but not limited, to areas such as personal computers, server computers, memory modules, graphics chips, radar and radio-frequency (RF) devices, disc drives, displays, including light-emitting diode (LED) displays, lighting systems, automotive control units, power-electronics, solar cells, batteries, communications equipment, such as cellular phones, thermoelectric generators, and imaging equipment, including MRIs.

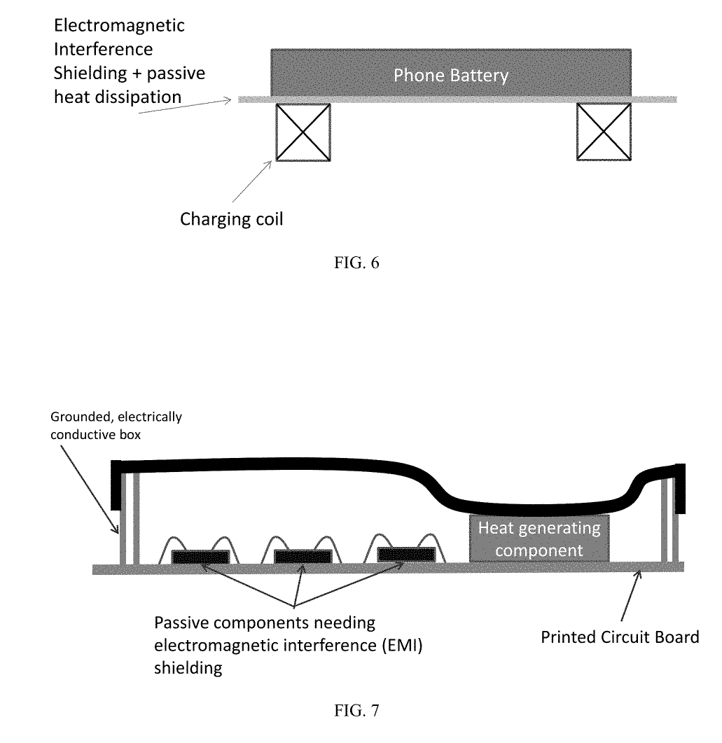

In yet other applications, the PCM-CNT-substrates disclosed herein can be used to provide a combination of electromagnetic interference (EMI) shielding in combination with passive heat dissipation properties (such as heat spreading, heat storage, heat transfer), such as when used in consumer electronics including but not limited to batteries in devices (such as phones) and on printed circuit boards, which have components which may require both EMI shielding in addition to requiring dissipation of heat from heat generating components (see FIGS. 6 and 7). “EMI shielding,” as used herein refers to the ability to shield and/or block electromagnetic radiation either completely or substantially, as compared to an unshielded reference. “Substantially,” as used herein in the context of EMI shielding, refers to the ability to shield, block, and/or reduce electromagnetic radiation by at least about a 90%, 91%, 92%, 93%, 94%, 95%, 96%, 96%, 97%, 98%, 99%, 99.1%, 99.2%, 99.3%, 99.4%, 99.5%, 99.6%, 99.7%, 99.8%, or 99.9%.

### Example

Stacked Composite Manufacture:

A stacked PCM-CNT-substrate composite having multiple tiers of CNTs on metal substrates was prepared according to the methods described above. Each tier of composite had 50 μm CNTs on 50 μm aluminum foil and which were infiltrated by paraffin wax. The stacked composite was formed of up to 18 layers of individual composites and each stacked PCM-CNT-substrate composite was approximately 1″×1″ square.

Composite Testing:

The stacked composite was applied to an Android 4.4 device with a Samsung™ Octacore Exynos™ processor. For purposes of comparison, control devices having a bare die and a commercial aluminum heat sink were prepared. The bare die device was throttled after 6 cycles, the heat sink device was throttled for 11 cycles, and the stacked composite device was throttled for 10 cycles.

As shown in FIG. 4, the bare die device failed due to overheating at less than 60 minutes and exhibited the highest maximum chip temperature as compared to the other devices. The stacked composite device, with a total volume of 62 mm³, showed similar to superior performance, as compared to the commercial aluminum heat sink device, with a notably larger total volume of 160,000 mm³.

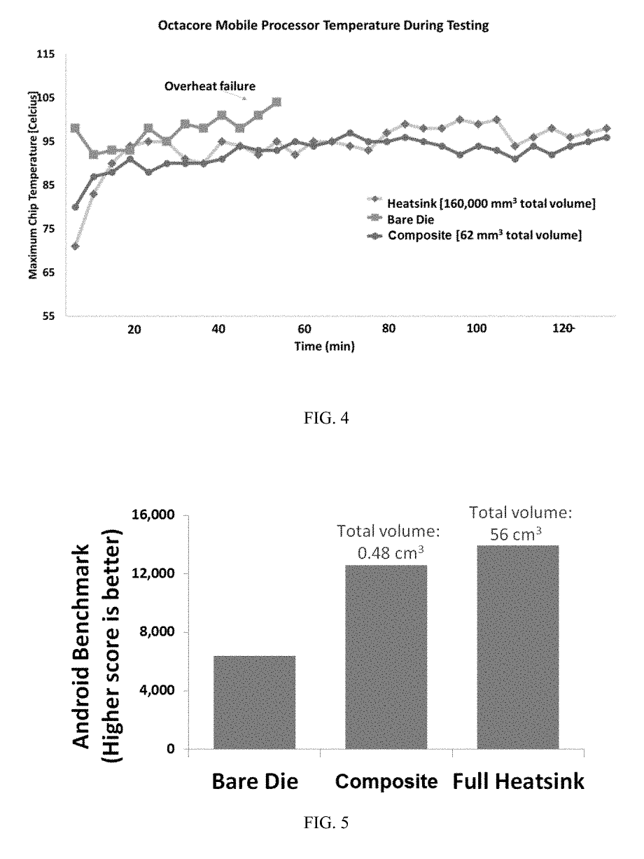

As shown in FIG. 5, when tested using an Android™ benchmark (where a higher number is better), the composite device exhibited comparable performance to the heat sink device. Notably, however, the stacked composite device had a total volume (0.48 cm³) which was approximately 117 times lower than the total volume of the heat sink device (56 cm³). This demonstrates that the composites described herein can function as well as a commercial heat sink but require much lower volumes.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

We claim:

1. A composite material comprising:
a phase change material;
vertically aligned carbon nanotube array supported on a substrate; and
wherein all or substantially all void space present within the vertically aligned carbon nanotubes (CNTs) is filled by the phase change material.

2. The composite material of claim 1, wherein the substrate is comprises a metal.

3. The composite material of claim 1, wherein the composite material is in thermal communication with a heat generating source.

4. The composite material of claim 3, wherein the heat generating source is an electronic device selected from the group consisting of a microchip, power conversion device, radio frequency communications module, and optoelectronics device.

5. The composite material of claim 1, wherein the composite comprises a stack of two or more tiers of the vertically aligned CNT arrays supported on the substrates.

6. The composite material of claim 5, wherein the interfacing tiers between the two or more of the vertically aligned CNTs are interdigitated within one another.

7. The composite material of claim 1, wherein the phase change material is infiltrated into the vertically aligned CNT array via application of the phase change material and a solvent solution mixture to the carbon nanotube array and subsequently the solvent is evaporated following infiltration.

8. The composite material of claim 1, wherein the phase change material is infiltrated into the vertically aligned CNT array through capillary action or wicking of the phase change material.

9. The composite material of claim 1, wherein the surface energy of the vertically aligned CNT array is modified through deposition of metals or ceramics.

10. The composite material of claim 1, wherein the phase change material is infiltrated into the array as a solid particulate form.

11. The composite material of claim 10, wherein the solid particulates are sized such that their average diameter is smaller than the nanotube-to-nanotube spacing within the CNT array.

12. The composite material of claim 1, wherein the phase change material is infiltrated into the vertically aligned CNT array via electro-deposition of the phase change material onto the surface of the vertically aligned CNTs.

13. The composite material of claim 4, wherein the phase change material melts or solidifies at a temperature at or near the operating temperature of the electronic device.

14. The composite material of claim 4, wherein the phase change material melts or solidifies at a temperature above the operating temperature of the electronic device.

15. The composite material of claim 1, wherein the phase change material further provides structural integrity to the vertically aligned CNT array.

16. The composite material of claim 1, wherein the phase change material imparts adhesive properties to the metal substrate.

17. The composite material of claim 1, wherein the vertically aligned CNT array provides stress relief for the phase change material by providing structural reinforcement and load bearing when the composite material is subjected to compression, tension, or both.

18. The composite material of claim 1, wherein the composite material is flexible allowing it to be contoured to fit internal geometry of an electronic package and to have thermal communication with more than one heat generating surface at a time.

19. The composite material of claim 1, wherein the composite material is present within a container.

20. The composite material of claim 4, wherein the composite material is in thermal communication with the electronic device and the surrounding atmosphere.

21. The composite material of claim 20, wherein the composite material is in thermal communication with the electronic device and in thermal communication with a secondary thermal solution selected from a heat sink, cold plate, spreader, or heat pipe.

22. The composite material of claim 20, wherein the composite material improves heat transfer between the electronic device and the secondary thermal solution.

23. The composite material of claim 1, wherein the substrate acts as an extended surface area for heat transfer.

24. The composite material of claim 1, wherein the carbon nanotubes of the array efficiently reject heat to surroundings via radiation.

25. The composite material of claim 1, wherein the substrate provides the composite material a higher in plane thermal conductivity than cross plane thermal conductivity.

26. The composite material of claim 1, wherein the composite material is flexible and conformable to a three dimensional surface.

27. The composite material of claim 4, wherein the composite material is in thermal communication with the electronic device and the device operates in transient or limited duration fashion.

28. The composite material of claim 4, wherein power consumption of the electronic device may be temporarily enhanced to improve performance during a high demand activity.

29. The composite material of claim 1, wherein at least a portion of the phase change material is a thermoplastic adhesive which is applied conformal to the carbon nanotube array.

30. The composite material of claim 29, wherein the thermoplastic adhesive is a coating having a thickness of less 5,000 nm and wherein the thermoplastic adhesive coating does not add thermal resistance to the composite material.

31. The composite material of claim 1, wherein the composite material provides shielding against electromagnetic interference.

32. The composite material of claim 1, wherein the composite simultaneously provides electromagnetic interference shielding and heat spreading, heat storage, heat transfer, or other heat dissipation properties.

33. A method of making a composite material, the method comprising:
providing one or more vertically aligned carbon nanotube arrays supported on a substrate; and
infiltrating a phase change material to the vertically aligned carbon nanotube arrays supported on a substrate wherein all or substantially all void space present within the vertically aligned carbon nanotubes (CNTs) is filled by the phase change material.

34. The method of claim 33, wherein the phase change material wets the CNTs and infiltrates the CNT array via capillary action or wicking action.

35. The method of claim 33, wherein the phase change material is infiltrated via spray coating or powder coating.

36. The method of claim 33, wherein the carbon nanotube arrays are coated with, dispersed within, infiltrated by, or filled in with the phase change material selected from polymeric, non-polymeric, low melting temperature metal or metal alloys, or combinations thereof.

37. The method of claim 33, wherein the phase change material is an oligomeric or polymeric material.

38. The method of claim 38, wherein the polymeric material is an adhesive.

39. The method of claim 38, wherein the adhesive is selected from the group consisting of polyurethanes, nylons, styrenic block copolymers, olefins, poly(olefins), thermoplastic vulcanizates, polyesters, copolyesters, polyamides, and combinations thereof.

40. The method of claim 33, wherein the phase change material conformally coats the carbon nanotubes.

41. The method of claim 33, wherein the phase change material is infiltrated into the vertically aligned CNT array via application of a phase change material and solvent solution mixture to the array and subsequently the solvent is evaporated following infiltration.

42. The method of claim 33, further comprising the step of:
stacking at least two infiltrated vertically aligned CNT arrays supported on the substrates.

43. The method of claim 43, wherein the stacked arrays form interfacing tiers between the two or more of the vertically aligned CNTs which are interdigitated within one another.

44. The method of claim 44, wherein the number of interfacing tiers in the stack is 2, 3, 4, 5, 6, 7, 8, 9, 10, 11, 12, 13, 14, 15, 16, 17, 18, 19, 20, 21, 22, 23, 24, or 25.

45. The method of claim 44, wherein degree of interdigitation between interfacing tiers is at least about 5%, 10%, 20%, 30%, 40%, 50%, 60%, 70%, 75%, 80%, 85%, 90%, 95%, 96%, 97%, 98%, 99%, or 99.9%.

46. A device comprising the composite material defined in claim 1.
